(19) United States
(12) Patent Application Publication
(10) Pub. No.: US 2025/0105114 A1
(43) Pub. Date: Mar. 27, 2025

(54) N-BALL SECOND LEVEL INTERCONNECT PACKAGE ARCHITECTURE

(71) Applicant: Intel Corporation, Santa Clara, CA (US)

(72) Inventors: Alexander W. HUETTIS, Hillsboro, OR (US); Patrick NARDI, Scottsdale, AZ (US); Abid AMEEN, Chandler, AZ (US); Jiaqi WU, Chandler, AZ (US); Andrew W. CARLSON, Chandler, AZ (US)

(21) Appl. No.: 18/373,879

(22) Filed: Sep. 27, 2023

(51) Int. Cl. H01L 23/498

(52) U.S. Cl. CPC H01L 23/49816; H01L 23/49838; H01L 23/49866

(57) ABSTRACT

Embodiments disclosed herein include systems with interconnects that comprise four or more different interconnect types. In an embodiment, an apparatus comprises a substrate and a ball grid array across a surface of the substrate. In an embodiment, the ball grid array comprises first interconnects in a first region of the ball grid array, second interconnects in a second region of the ball grid array, third interconnects in a third region of the ball grid array, and fourth interconnects in a fourth region of the ball grid array. In an embodiment, the first interconnects, the second interconnects, the third interconnects, and the fourth interconnects all have a difference in one or more of a composition, a dimension, and a structure.

### BACKGROUND

High temperature warpage of a finished electronic package is a key technological package design element that determines the final yield and quality during attachment of the package substrate to the board (e.g., a motherboard) via surface mount technology (SMT). The interconnect between the package substrate and the board is typically referred to as a second level interconnect (SLI). In one type of SLI architecture, the individual interconnects are solder balls or the like. The use of solder can result in several defects that need to be addressed. More particularly, as warpage increases, the number of defects also increases. This can negatively impact yield.

One option to improve the yield of SLI structures is to decrease the effect of warpage of the package substrate. The effect of warpage may be decreased at the time of SMT using a weighted reflow process to flatten the package. However, such processes are technologically premature, cost prohibitive, and are an additional burden on assembly processes. Further, the assembly ecosystem would need to be changed in order to enable widespread use of such processes.

Another approach is to increase the package substrate core thickness or reduce die size. This has a negative impact on overall package thickness (i.e., Z-height), as well as increasing the cost of the substrate. Electrical and thermal performance may also be negatively impacted by such design changes.

### BRIEF DESCRIPTION OF THE DRAWINGS

FIG. 1A is a cross-sectional illustration of a package substrate that includes warpage, in accordance with an embodiment.

FIG. 1B is a cross-sectional illustration of an electronic package with a warped package substrate that is coupled to a board with interconnects that include different defects, in accordance with an embodiment.

FIG. 2A is a cross-sectional illustration of an electronic package with second level interconnects (SLIs) that include three different interconnect architectures, in accordance with an embodiment.

FIG. 2B is a plan view illustration of the electronic package in FIG. 2A with three different interconnect architectures, in accordance with an embodiment.

FIG. 3A is a cross-sectional illustration of an electronic package with three different interconnect architectures, where one of the interconnect architectures includes a core with a solder shell, in accordance with an embodiment.

FIG. 3B is a plan view illustration of the electronic package in FIG. 3A with three different interconnect architectures, in accordance with an embodiment.

FIG. 4A is a cross-sectional illustration of an electronic package with three different interconnect architectures, where one of the interconnect architectures has a larger diameter than the other interconnect architectures, in accordance with an embodiment.

FIG. 4B is a plan view illustration of the electronic package in FIG. 4A with three different interconnect architectures, in accordance with an embodiment.

FIG. 5A is a plan view illustration of a package substrate that shows general positioning of the three different interconnect architectures, in accordance with an embodiment.

FIG. 5B is a plan view illustration of a package substrate with first and second interconnects in corner regions and third interconnects in a central region, in accordance with an embodiment.

FIG. 6A is a plan view illustration of a package substrate that shows general positioning of the three different interconnect architectures, in accordance with an embodiment.

FIG. 6B is a plan view illustration of a package substrate with first interconnects in corner regions, second interconnects in an intermediate region, and third interconnects in a center region, in accordance with an embodiment.

FIG. 7 is a cross-sectional illustration of an electronic system that includes a board coupled to a package substrate by SLIs that comprise at least three different types of interconnect architectures, in accordance with an embodiment.

FIG. 8A is a cross-sectional illustration of an electronic system with a plurality of interconnects that include different material compositions, in accordance with an embodiment.

FIG. 8B is a cross-sectional illustration of an electronic system with a plurality of interconnects that include different structures, in accordance with an embodiment.

FIG. 8C is a cross-sectional illustration of an electronic system with a plurality of interconnects that include different dimensions, in accordance with an embodiment.

FIG. 9A is a plan view illustration of a package substrate with a plurality of different interconnect regions, in accordance with an embodiment.

FIG. 9B is a plan view illustration of a package substrate with a plurality of different interconnect regions, in accordance with an additional embodiment.

FIG. 10 is a cross-sectional illustration of an electronic system that includes second level interconnects that include interconnects that are different from each other, in accordance with an embodiment.

FIG. 11 is a schematic of a computing device built in accordance with an embodiment.

### EMBODIMENTS OF THE PRESENT DISCLOSURE

Described herein are electronic systems, and more particularly, second level interconnect (SLI) architectures that include a plurality of different interconnect solutions, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

As noted above, warpage of the package substrate is an important aspect of assembly that should be controlled in order to improve assembly yields. In one approach, the warpage of the package substrate is reduced using a weighted reflow process to flatten the package. In other approaches, the structure of the package substrate is changed to reduce warpage. For example, a core thickness of the package substrate may be increased.

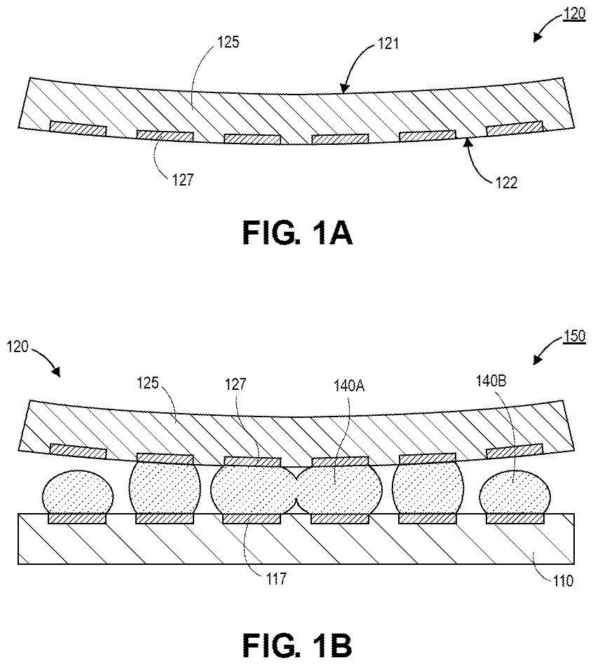

Warpage mitigation allows for fewer defects in the interconnects between the package substrate and the board (e.g., a motherboard). For example, solder bump bridging or non-contact opens are some of the defects that can be observed when there is warpage in the package substrate. The warpage mitigation processes described above may reduce, but not eliminate, such defects. Further, the warpage mitigation processes are expensive, and not manufacturing friendly with existing assembly ecosystems. An example of a warped package substrate 120 is shown in the cross-sectional illustration of FIG. 1A. As shown, the package substrate 120 may include a substrate 125.

The substrate 125 may be an organic package substrate. For example, laminated buildup layers may be used to form the substrate 125. In an embodiment, a core (not shown) may be provided within the substrate 125. The core may be an organic core, a glass core, or the like. In the case of a glass core, the core may comprise substantially all glass. That is, the glass core is distinct from an organic core with glass fiber reinforcements. The glass core may be substantially all glass. The glass core may be a solid material with an amorphous crystal structure. More particularly, the glass core may be any suitable glass formulation that has the necessary mechanical robustness and compatibility with semiconductor packaging manufacturing and assembly processes. For example, the glass core may comprise aluminosilicate glass, borosilicate glass, alumino-borosilicate glass, silica, fused silica, or the like. In some embodiments, the glass core may include one or more additives, such as, but not limited to, Al₂O₃, B₂O₃, MgO, CaO, SrO, BaO, SnO₂, Na₂O, K₂O, SrO, P₂O₃, ZrO₂, Li₂O, Ti, and Zn. More generally, the glass core may comprise silicon and oxygen, as well as any one or more of aluminum, boron, magnesium, calcium, barium, tin, sodium, potassium, strontium, phosphorus, zirconium, lithium, titanium, and zinc. In an embodiment, the glass core may comprise at least 23 percent silicon (by weight) and at least 26 percent oxygen (by weight). In some embodiments, the glass core may further comprise at least 5 percent aluminum (by weight). In an embodiment, conductive routing (not shown) may be provided through the substrate 125. For example, pads, traces, vias, etc. may be fabricated within the layers of the substrate 125 in order to provide conductive routing through the substrate 125.

The package substrate 120 may comprise a first surface 121 and a second surface 122 opposite from the first surface 121. The first surface 121 and the second surface 122 may be non-planar. That is, the first surface 121 and the second surface 122 may be described as being warped in some embodiments. In the illustration shown in FIG. 1A, the warpage is shown so that the substrate 125 curves upward. Though, in other embodiments, warpage may be in the opposite direction so that the substrate 125 curves downward. Also, while a single curve is shown, in some instances multiple curves may be provided along the surfaces 121 and 122.

In an embodiment, pads 127 may be provided along the second surface 122 of the substrate 125. The pads 127 may be locations where second level interconnects (SLIs) are attached in a subsequent processing operation. For example, the SLIs may be solder balls or the like. The pads 127 may conform to the warpage of the second surface 122.

Referring now to FIG. 1B, a cross-sectional illustration of an electronic system 150 is shown, in accordance with an embodiment. The electronic system 150 may include a package substrate 120 and a board 110, such as a printed circuit board (PCB). Though, embodiments may include any two substrates that are coupled together by interconnects. In an embodiment, the package substrate 120 may be similar to the package substrate 120 described in greater detail above with respect to FIG. 1A. For example, the package substrate 120 may include a substrate 125 with pads 127.

In an embodiment, the substrate 125 is warped. The warpage may be so that the substrate 125 is curved up. Though, the opposite warpage direction is also possible. In an embodiment, the board 110 is not warped. That is, the top and bottom surfaces of the board 110 may be substantially planar. Though, in other embodiments the board 110 may also be warped. The degree and direction of the warpage of the board 110 may be different than the degree and direction of the warpage of the substrate 125.

In an embodiment, interconnects 140 may couple the pads 127 of the substrate 125 to the pads 117 of the board 110. The interconnects 140 may be SLIs in some instances. The interconnects 140 may be any suitable SLI architecture, such as solder balls or the like. In one embodiment, the interconnects 140 may all be substantially the same. That is, the interconnects 140 may be the same material composition and have the same volume.

However, due to the warpage, there may be one or more interconnect defects between the package substrate 120 and the board 110. For example, at the center of the electronic system 150, a pair of interconnects 140A may be coupled together. Such a defect may be referred to as solder bump bridging. This type of defect generates a short circuit between adjacent interconnects and can lead to defective electronic systems 150. An additional example of a defect is shown at the edges of the electronic system 150. There, interconnects 140B do not form a complete connection between pads 117 and pads 127. Such a defect can be referred to as a non-contact open. This results in an open circuit that leads to defective electronic systems 150 as well.

In some implementations, solutions to such defects have been proposed. For example, a first type of interconnect can be provided at a center of the electronic system 150 and a second type of interconnect can be provided at an edge of the electronic system 150. For example, the use of a copper core interconnect can lead to reductions in the presence of solder bump bridging. However, the issues with non-contact open defects may still remain. As such, solutions to the defects are limited to warpage reduction approaches, which have limitations such as those listed above.

Accordingly, embodiments disclosed herein provide a new approach to reducing defects by modifying the SLIs instead of dealing with the warpage. For example, the interconnects may include three different types of interconnect architectures. In one embodiment, a first interconnect may include a typical low temperature solder (LTS) with a first diameter, the second interconnect may include a LTS with a second (larger) diameter, and the third interconnect may include a copper core interconnect. In another embodiment, a first interconnect may include a LTS with a first material composition, a second interconnect may include a solder with a second material composition, and a third interconnect may include a copper core interconnect.

In an embodiment, the copper core interconnects may be provided proximate to corner regions of the bump field. For example, four copper core interconnects may be provided, one at each corner. The larger diameter interconnects may also be provided in an array proximate to corner regions. The larger diameter provides additional margin in order to accommodate warpage and prevent non-contact opens.

In another embodiment, the copper core interconnects may be provided proximate to the corner regions of the bump field. The LTS may be provided in an intermediate region of the bump field, and the third interconnects may be provided at a central region of the bump field. The third interconnects may have a material composition that is beneficial for power delivery improvements. For example, the LTS may comprise bismuth and tin, and the second composition may comprise tin, silver, and copper (e.g., a SAC alloy).

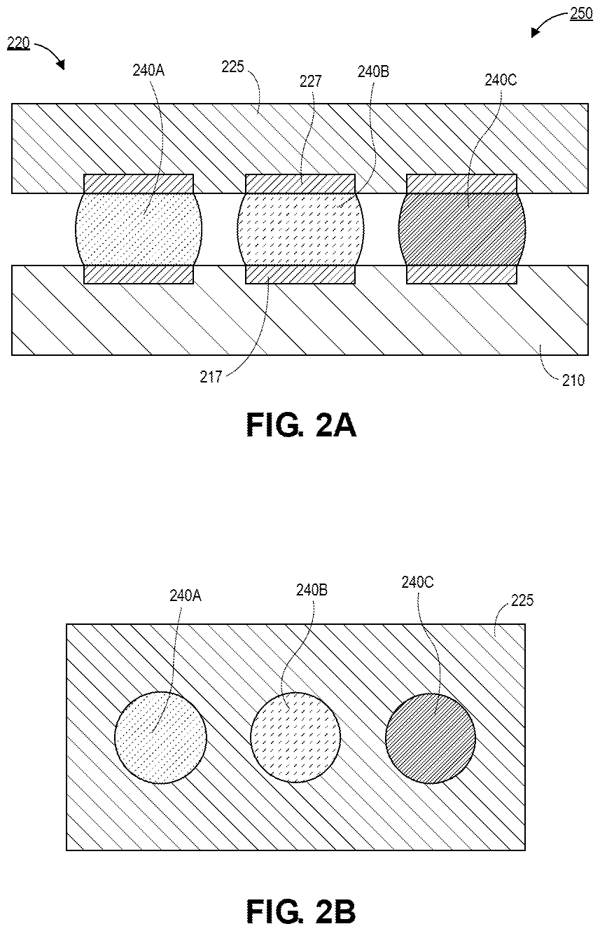

Referring now to FIG. 2A, a cross-sectional illustration of an electronic system 250 is shown, in accordance with an embodiment. In an embodiment, the electronic system 250 may comprise a board 210 that is coupled to a package substrate 220. Though, it is to be appreciated that any two types of substrates may be coupled together by similar interconnect architectures in other embodiments. In an embodiment, the board 210 may be a PCB or other motherboard architecture. The package substrate 220 may comprise a substrate 225. The substrate 225 may be an organic substrate with, or without, a core (not shown). The substrate 225 may include conductive routing (not shown), such as pads, traces, vias, etc. in order to provide conductive routing through the package substrate 220.

In an embodiment, SLI pads 227 may be provided on a bottom of the substrate 225. In the illustrated embodiment, the SLI pads 227 are recessed into the surface of the substrate 225. Though, in other embodiments, the SLI pads 227 may extend past the bottom surface of the substrate. Similarly, SLI pads 217 may be provided in board 210. The SLI pads 217 may be recessed into the top surface of the board 210 or extend up past a top surface of the board 210.

In an embodiment, interconnects 240 may be provided between the board 210 and the package substrate 220. The interconnects 240 may electrically couple the SLI pads 217 on the board 210 to the SLI pads 227 on the substrate 225. The interconnects 240 may be any SLI architecture. Generally, the interconnects 240 may be solder interconnects. However, three different types of interconnects 240 may be provided between the board 210 and the package substrate 220. For example, interconnects 240A, interconnect 240B, and interconnect 240C are provided in FIG. 2A.

The interconnects 240A, 240B, and 240C are shown with different shadings in order to indicate that they are different types of interconnects 240. More specifically, the interconnects 240A, 240B, and 240C may all be different from each other. The differences between the interconnects 240 may arise out of various parameters. In one instance a diameter of the interconnects 240 may be different from each other. In another embodiment, a material composition of the interconnects 240 may be different from each other. In yet another embodiment, the structure of the interconnects 240 may be different from each other.

In the illustrated embodiment, the interconnects 240A, 240B, and 240C are shown as all being adjacent to each other for convenience. In other embodiments, the interconnects 240A, 240B, and 240C may be provided in different regions of the bump field. Further, while single instances of interconnects 240A, 240B, and 240C are shown, it is to be appreciated that any number of interconnects 240 for each type may be included in the electronic system 250. A number of instances of each type of interconnect 240A, 240B, and 240C may also be different from each other.

Referring now to FIG. 2B, a plan view illustration of a portion of the substrate 225 is shown, in accordance with an embodiment. In an embodiment, the interconnects 240A, 240B, and 240C may be provided over a surface of the substrate 225. As described above, the interconnects 240A, 240B, and 240C may be different from each other. While shown as having substantially similar diameters, each of the interconnects 240 may have different diameters, as will be described in greater detail below. In an embodiment, the interconnects 240A, 240B, and 240C may be spaced at a substantially similar pitch. Though, in other embodiments the interconnects 240A, 240B, and 240C may have non-uniform pitches.

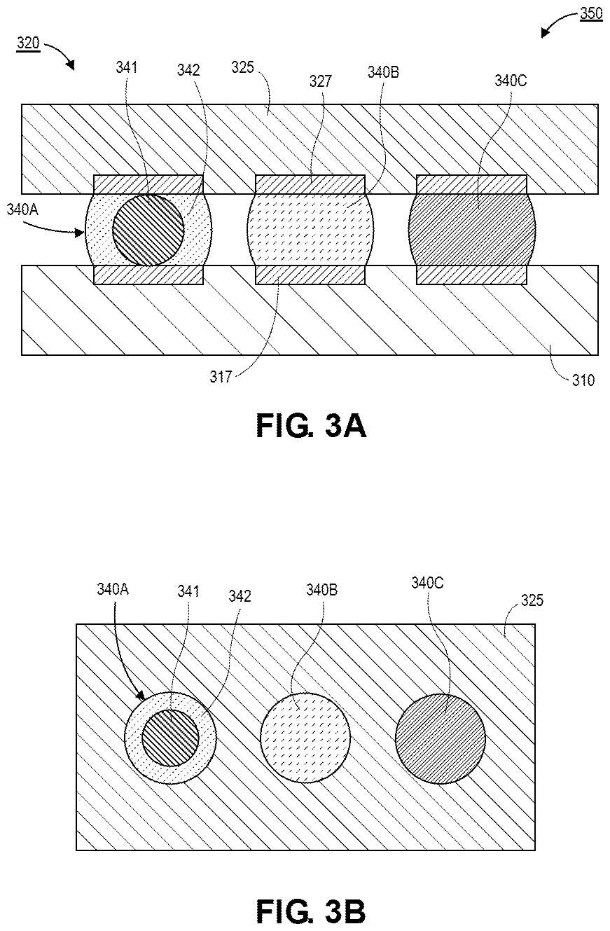

Referring now to FIG. 3A, a cross-sectional illustration of an electronic system 350 is shown, in accordance with an embodiment. In an embodiment, the electronic system 350 may comprise a board 310 that is coupled to a package substrate 320. Though, it is to be appreciated that any two types of substrates may be coupled together by similar interconnect architectures in other embodiments. In an embodiment, the board 310 may be a PCB or other motherboard architecture. The package substrate 320 may comprise a substrate 325. The substrate 325 may be an organic substrate with, or without, a core (not shown). The substrate 325 may include conductive routing (not shown), such as pads, traces, vias, etc. in order to provide conductive routing through the package substrate 320.

In an embodiment, SLI pads 327 may be provided on a bottom of the substrate 325. In the illustrated embodiment, the SLI pads 327 are recessed into the surface of the substrate 325. Though, in other embodiments, the SLI pads 327 may extend past the bottom surface of the substrate. Similarly, SLI pads 317 may be provided in board 310. The SLI pads 317 may be recessed into the top surface of the board 310 or extend up past a top surface of the board 310.

In an embodiment, interconnects 340 may be provided between the board 310 and the package substrate 320. The interconnects 340 may electrically couple the SLI pads 317 on the board 310 to the SLI pads 327 on the substrate 325. The interconnects 340 may be any SLI architecture. Generally, the interconnects 340 may be solder interconnects. However, three different types of interconnects 340 may be provided between the board 310 and the package substrate 320. For example, interconnects 340A, interconnect 340B, and interconnect 340C are provided in FIG. 3A.

In an embodiment, the interconnects 340A, 340B, and 340C are different from each other. For example, the first interconnect 340A may have a different structure than the second interconnect 340B and the third interconnect 340C. As indicated by the shading, the second interconnect 340B may have a different material composition than the third interconnect 340C.

The first interconnect 340A may be a multi-layer interconnect 340. For example, the first interconnect 340A may include a core 341 and an outer shell 342. The core 341 may have a melting temperature that is higher than a melting temperature of the outer shell 342. For example, the melting temperature of the core 341 may be higher than the reflow temperature, and the melting temperature of the shell 342 may be around the reflow temperature. In a particular embodiment, the core 341 may comprise copper or the like, and the shell 342 may comprise a solder. For example, the solder of the shell 342 may comprise tin and bismuth in some embodiments.

In an embodiment the material composition of the second interconnect 340B may have different elemental constituents than the material composition of the third interconnect 340C. For example, the second interconnect 340B may comprise tin and bismuth, and the third interconnect 340C may comprise tin, silver, and copper (e.g., a SAC alloy). In other embodiments, the second interconnect 340B and the third interconnect 340C may include the same elemental constituents with different weight percentages. For example, a difference in the weight percent of an element may be approximately one percent or greater.

Referring now to FIG. 3B, a plan view illustration of a portion of the substrate 325 is shown, in accordance with an embodiment. In an embodiment, the interconnects 340A, 340B, and 340C may be provided over a surface of the substrate 325. As described above, the interconnects 340A, 340B, and 340C may be different from each other. For example, first interconnect 340A may be a multi-layer interconnect with a core 341 and a shell 342. The second interconnect 340B and the third interconnect 340C may have different material compositions.

While shown as having substantially similar diameters, each of the interconnects 340 may have different diameters, as will be described in greater detail below. In an embodiment, the interconnects 340A, 340B, and 340C may be spaced at a substantially similar pitch. Though, in other embodiments the interconnects 340A, 340B, and 340C may have non-uniform pitches.

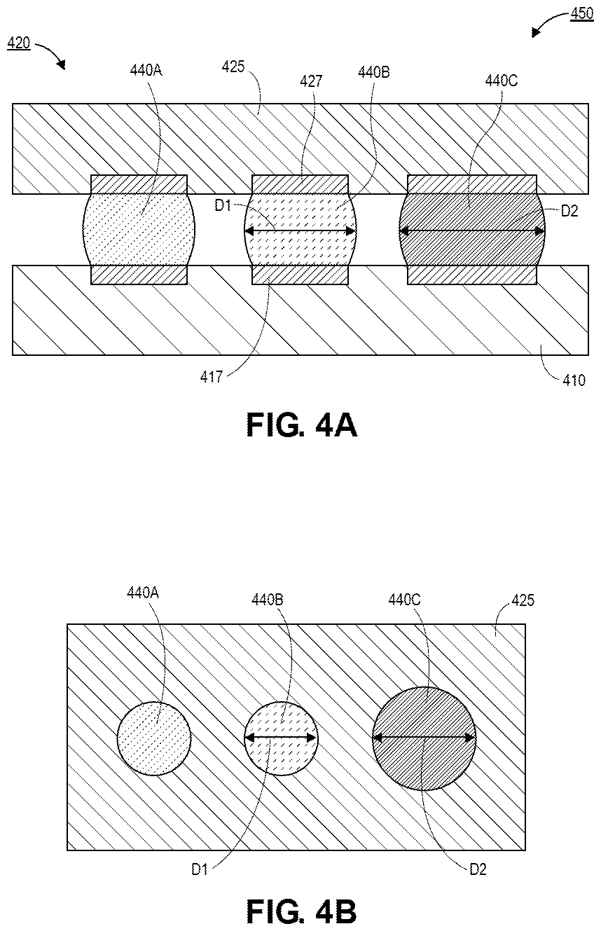

Referring now to FIG. 4A, a cross-sectional illustration of an electronic system 450 is shown, in accordance with an embodiment. In an embodiment, the electronic system 450 may comprise a board 410 that is coupled to a package substrate 420. Though, it is to be appreciated that any two types of substrates may be coupled together by similar interconnect architectures in other embodiments. In an embodiment, the board 410 may be a PCB or other motherboard architecture. The package substrate 420 may comprise a substrate 425. The substrate 425 may be an organic substrate with, or without, a core (not shown). The substrate 425 may include conductive routing (not shown), such as pads, traces, vias, etc. in order to provide conductive routing through the package substrate 420.

In an embodiment, SLI pads 427 may be provided on a bottom of the substrate 425. In the illustrated embodiment, the SLI pads 427 are recessed into the surface of the substrate 425. Though, in other embodiments, the SLI pads 427 may extend past the bottom surface of the substrate. Similarly, SLI pads 417 may be provided in board 410. The SLI pads 417 may be recessed into the top surface of the board 410 or extend up past a top surface of the board 410.

In an embodiment, interconnects 440 may be provided between the board 410 and the package substrate 420. The interconnects 440 may electrically couple the SLI pads 417 on the board 410 to the SLI pads 427 on the substrate 425. The interconnects 440 may be any SLI architecture. Generally, the interconnects 440 may be solder interconnects. However, three or more different types of interconnects 440 may be provided between the board 410 and the package substrate 420. For example, interconnects 440A, interconnect 440B, and interconnect 440C are provided in FIG. 4A.

In an embodiment, the interconnects 440A, 440B, and 440C are different from each other. For example, the first interconnect 440A may have a different material composition than the second interconnect 440B and the third interconnect 440C. Further, one or more of the interconnects 440 may have different diameters than the other interconnects 440. For example, the second interconnect 440B may have a first diameter D1, and the third interconnect 440C may have a second diameter D2 that is larger than the first diameter D1. In an embodiment, the second diameter D2 may be approximately twenty percent different than the first diameter D1 at a similar stand-off height of solder with no greater than 10 percent difference (between the stand-off heights). As an example, in a particular embodiment, the first diameter D1 is approximately 150 μm and the second diameter D2 is approximately 200 μm, while the stand-off height is approximately 210 μm for first interconnect 440A and 220 μm for second interconnect 440B. In such an instance, the two interconnects 440A and 440B would be considered “different” from each other.

In an embodiment the material composition of the first interconnect 440A may have different elemental constituents than the material composition of the second interconnect 440B. For example, the first interconnect 440A may comprise tin and bismuth, and the second interconnect 440B may comprise tin, silver, and copper (e.g., a SAC alloy). In other embodiments, the first interconnect 440A and the second interconnect 440B may include the same elemental constituents with different weight percentages. For example, a difference in the weight percent of an element may be approximately one percent or greater.

Referring now to FIG. 4B, a plan view illustration of a portion of the substrate 425 is shown, in accordance with an embodiment. In an embodiment, the interconnects 440A, 440B, and 440C may be provided over a surface of the substrate 425. As described above, the interconnects 440A, 440B, and 440C may be different from each other. For example, the second interconnect 440B may have a first diameter D1 that is different than the second diameter D2 of the third interconnect 440C while the standoff height is same. While shown as having different shadings, the second interconnect 440B may have the same material composition as the third interconnect 440C. That is, the only difference may be in the volume of the interconnects 440.

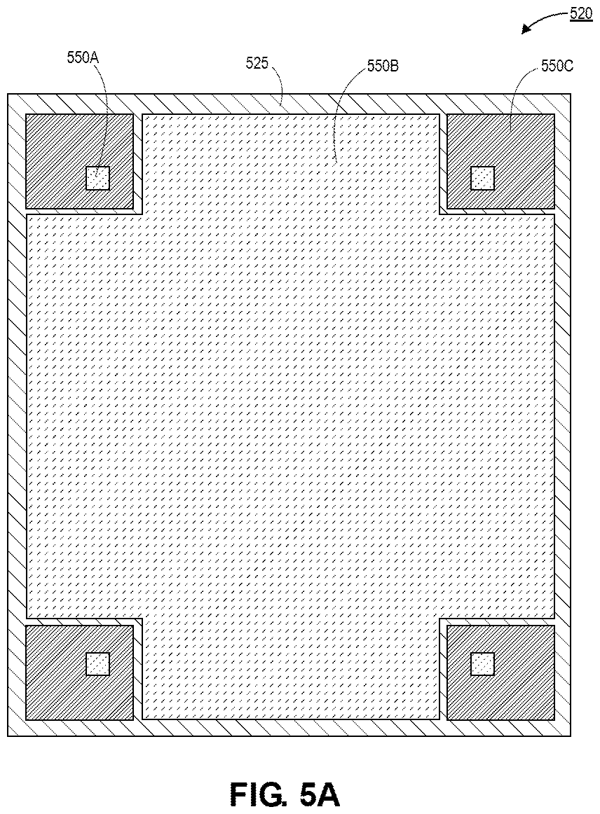

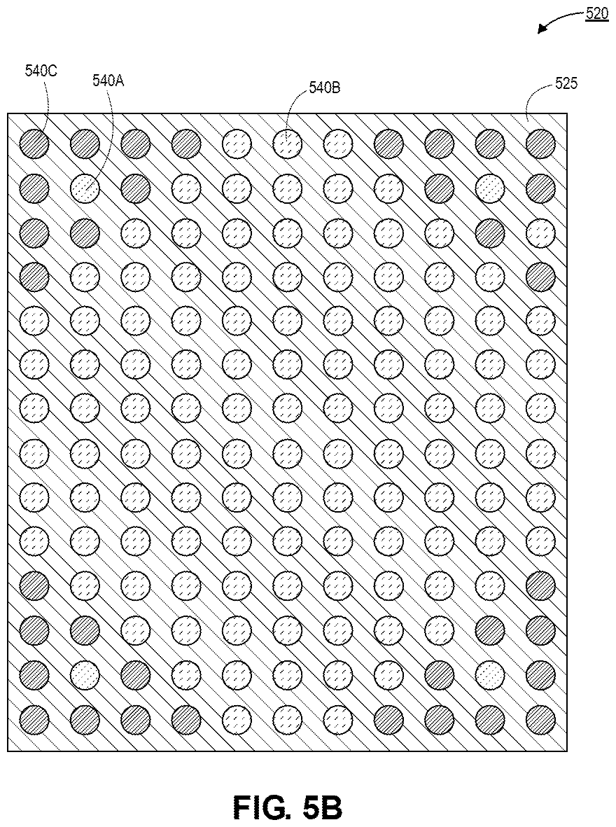

In order to mitigate non-contact open and solder bump bridging defects the different interconnect types may be distributed across different regions of the package substrate. An example of such an embodiment is shown in FIG. 5A.

Referring now to FIG. 5A, a plan view illustration of a package substrate 520 is shown, in accordance with an embodiment. In an embodiment, the package substrate 520 comprises a substrate 525. The substrate 525 may be divided into a plurality of regions.

First regions 550A may be provided proximate to corners of the substrate 525. For example, four first regions 550A are provided on the substrate 525. The first regions 550A may be locations where interconnects with a two layer architecture are used. For example, interconnects in first regions 550A may comprise a core with a solder shell around the core. The interconnects in the first regions 550A may be used in order to provide a standoff height for the SLI. This can be used to minimize solder bump bridging.

In an embodiment, second region 550B may be provided as the main array of bumps for the package substrate 520. The second region 550B may include interconnects with a first material composition. For example, the second region 550B may include interconnects with a tin-bismuth solder or any other LTS composition. The interconnects in the second region 550B may have a first diameter.

In an embodiment, third regions 550C may be provided proximate to the corners of the package substrate 520. In an embodiment, the first regions 550A may be embedded within the third regions 550C. In some instances, the third regions 550C may have interconnects with a second diameter. The second diameter is larger than the first diameter in the second regions 550B. In an embodiment, the larger interconnects in the third region 550C allow for improved protection against non-contact open defects.

Referring now to FIG. 5B, a plan view illustration of the package substrate 520 is shown, in accordance with an additional embodiment. In an embodiment, the package substrate 520 may include first interconnects 540A, second interconnects 540B, and third interconnects 540C. The first interconnects 540A may include a two layer interconnect, such as ones including a core and a solder shell around the core. The second interconnects 540B may be an LTS with a first diameter. The third interconnects 540C may be an LTS with a second diameter that is different than the first diameter.

In an embodiment, first interconnects 540A are proximate to corners of the substrate 525. As used herein, being proximate to the corners may refer to an interconnect 540 that is within ten columns or rows of the absolute corner of the bump field. In an embodiment, the second interconnects 540B may be provided in an array within a center of the package substrate 520. The third interconnects 540C may also be provided proximate to the corner region of the bump field. In an embodiment, the first interconnects 540A may be within an array of the third interconnects 540C.

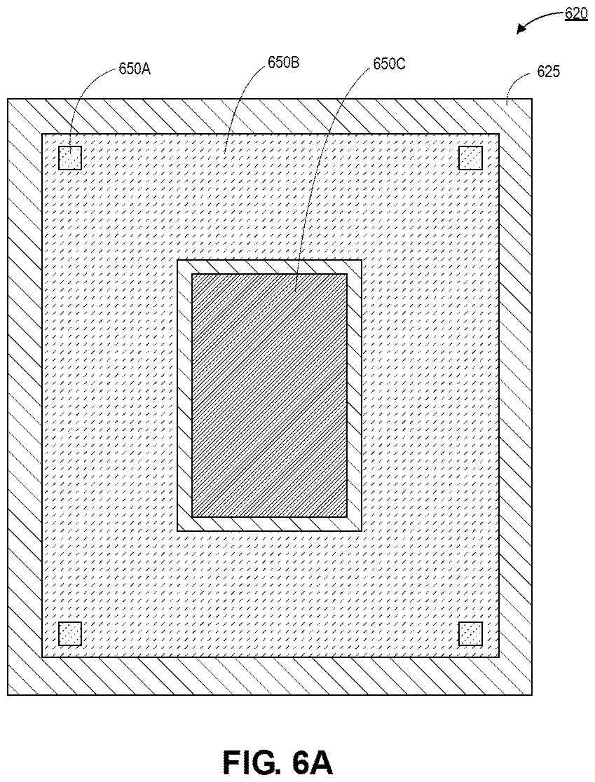

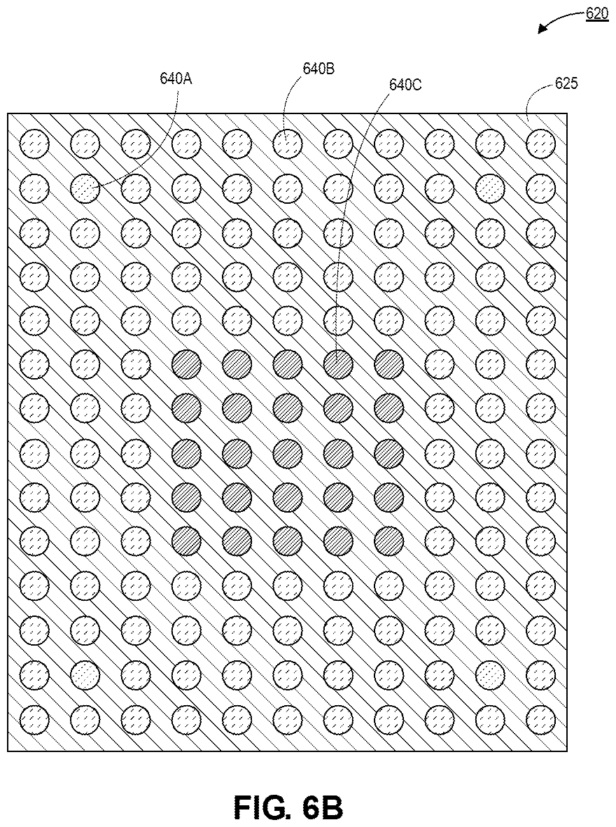

Referring now to FIG. 6A, a plan view illustration of a package substrate 620 is shown, in accordance with an embodiment. In an embodiment, the package substrate 620 comprises a substrate 625. The substrate 625 may be divided into a plurality of regions.

First regions 650A may be provided proximate to corners of the substrate 625. For example, four first regions 650A are provided on the substrate 625. The first regions 650A may be locations where interconnects with a two layer architecture are used. For example, interconnects in first regions 650A may comprise a core with a solder shell around the core. The interconnects in the first regions 650A may be used in order to provide a standoff height for the SLI. This can be used to minimize solder bump bridging.

In an embodiment, second region 650B may be provided as an intermediate array of bumps for the package substrate 620. The second region 650B may include interconnects with a first material composition. For example, the second region 650B may include interconnects with a tin-bismuth solder or any other LTS composition.

In an embodiment, third regions 650C may be provided at a center of the package substrate 620. In an embodiment, the third region 650C may be surrounded by the second region 650B. In some instances, the third region 650C may include interconnects with a second material composition that is different than the first material composition. For example, the second material composition may include tin, silver, and copper (e.g., a SAC solder). The second material composition may be suitable for improved power delivery performance compared to the first material composition.

Referring now to FIG. 6B, a plan view illustration of the package substrate 620 is shown, in accordance with an additional embodiment. In an embodiment, the package substrate 620 may include first interconnects 640A, second interconnects 640B, and third interconnects 640C. The first interconnects 640A may include a two layer interconnect, such as ones including a core and a solder shell around the core. The second interconnects 640B may be an LTS with a first material composition. The third interconnects 640C may be a second material composition that is different than the first material composition.

In an embodiment, first interconnects 640A are proximate to corners of the substrate 625. In an embodiment, the second interconnects 640B may be provided in an intermediate array around a center of the package substrate 620. The third interconnects 640C may be provided at a center of the package substrate 620. In an embodiment, the third interconnects 640C may be surrounded entirely by the array of second interconnects 640B.

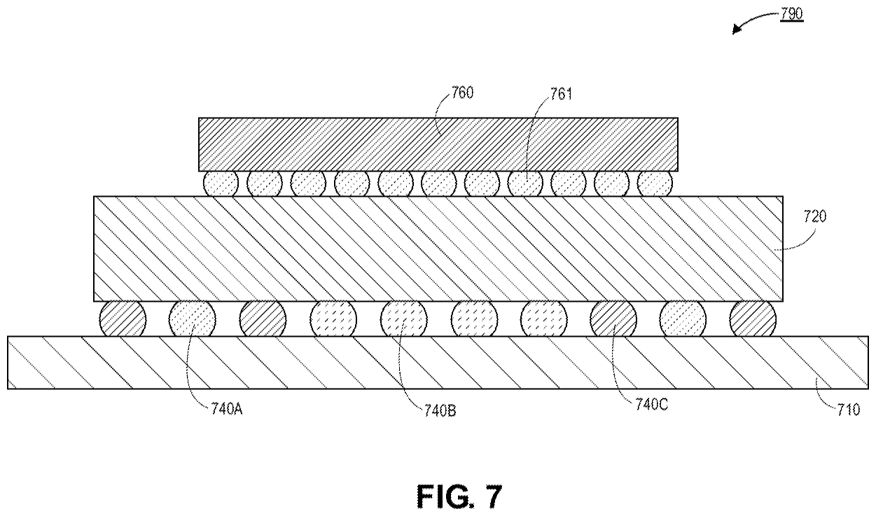

Referring now to FIG. 7, a cross-sectional illustration of an electronic system 790 is shown, in accordance with an embodiment. The electronic system 790 comprises a board 710 and a package substrate 720 coupled to the board 710. In an embodiment, SLIs are provided between the package substrate 720 and the board 710. The SLIs may include three or more different types of interconnects 740A, 740B, and 740C. The interconnects 740 may have differences that include one or more of material composition, volume (e.g., diameter), architecture (e.g., one material architecture or a core and shell architecture). The different interconnects 740 may be used in order to reduce SLI defects for warped substrates.

In an embodiment, one or more dies 760 may be coupled to the package substrate 720. First level interconnects (FLIs) 761 may couple the dies to the package substrate 720. The dies 760 may include any type of compute dies, including a central processing unit (CPU), a graphics processing unit (GPU), an XPU, a system on a chip (SoC), a communication die, or a memory die.

In the case of embodiments described above, examples that include three different interconnect architectures are provided. However, it is to be appreciated that embodiments are not limited to such architectures. Particularly, as package size increases, substrate thickness decreases, and other optimizations to packaging architectures are implemented, warpage can become an even greater problem. In such instances, the presence of four or more different interconnect architectures may be used to address the warpage issues. Accordingly, embodiments disclosed herein may also include packages with four, five, or more different interconnect architectures. The differences between the interconnects within a single level of the package may include one or more of elemental material composition, diameter, presence of a core, standoff height, or any other suitable difference. In addition to the interconnects themselves being different from each other, integration materials, such as flux, solder paste, epoxies, and the like can also be different from each other in order to further differentiate different interconnect types.

While variable interconnect architectures can be beneficial for accommodating warpage, embodiments are not limited to such benefits. That is, other beneficial properties for electronic package architectures can also be provided through the use of multiple different interconnect architectures. For example, electrical performance may be improved in some instances. Different material compositions provide different electrical properties. As such, high speed and/or high current interconnects can be implemented with material that has an electrical conductivity that is higher than that of other interconnects. In such instances, the interconnects may be segregated into different regions corresponding to the different electrical performance metrics that are necessary.

It is to be appreciated that the use of multiple different interconnect architectures does not significantly impact assembly complexity. Particularly, the interconnects are placed with pick and place tools in some instances. As such, the tool simply needs to pick the interconnect (e.g., solder ball) with the proper size, composition, etc. from a designated container.

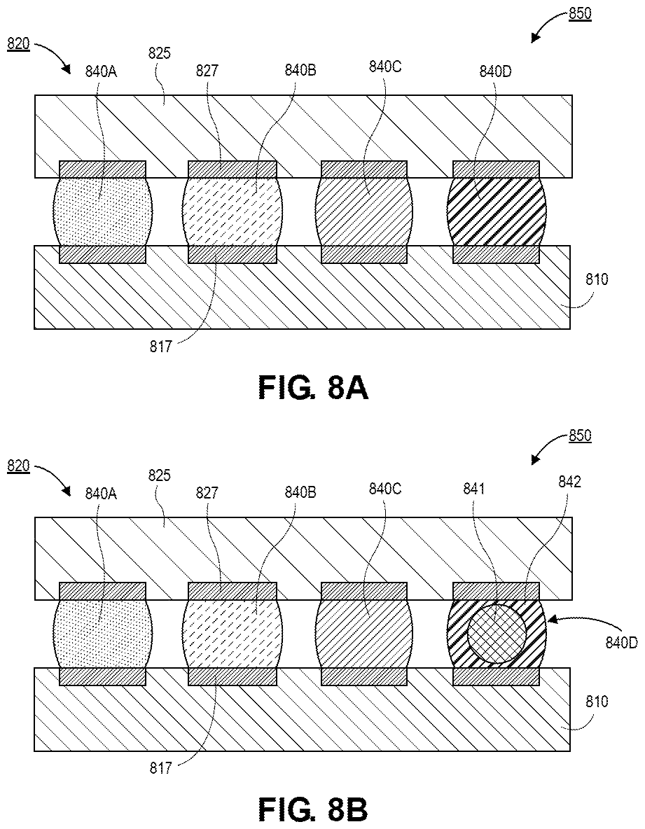

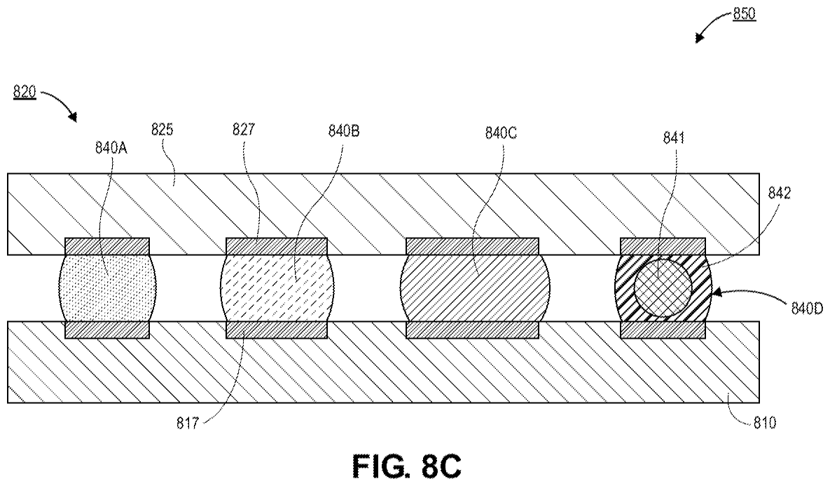

Referring now to FIGS. 8A-8C, a series of cross-sectional illustrations depicting various electronic systems 850 is shown, in accordance with various embodiments. In the illustrated embodiments, the electronic systems 850 are shown as having four different types of interconnects 840A-840D. Though, it is to be appreciated that embodiments are not limited to four different types of interconnects 840. In some instances, the electronic systems 850 may be referred to as having an n-ball solution. That is, any number of different types of interconnects 840 may be used. While it has been shown that four different interconnect 840 architectures are beneficial for existing electronic systems 850, electronic systems with fewer distinct interconnect 840 types or more distinct interconnect 840 types may be used in some embodiments. For example, an electronic system 850 may include two different interconnects 840, three different interconnects 840, four different interconnects 840, five different interconnects 840, six different interconnects 840, or even more than six different interconnects 840.

Additionally, while one example of each different interconnect 840A-840D is shown in FIGS. 8A-8C, embodiments are not limited to only having four interconnects 840. More generally, each electronic system 850 may have tens of interconnects 840, hundreds of interconnects 840, or thousands of interconnects 840 between the board 810 and the substrate 825. In some instances, the interconnects 840 between the board 810 and the substrate 825 may be considered as a ball grid array (BGA). Further, each different interconnect 840 type may be represented with different numbers of instances. For example, there may be less than ten of the first interconnects 840A in a single electronic system 850, and there may be greater than fifty second interconnects 840B in the single electronic system 850.

In FIGS. 8A-8C, the board 810 and the substrate 825 are shown as having substantially flat top and bottom surfaces. However, the top and/or bottom surfaces of the board 810 and the substrate 825 may have one or more curves due to warpage or the like. In situations where warpage exists, the edges of the board 810 and the substrate 825 may have a first spacing from each other, and the center of the board 810 and the substrate 825 may have a second spacing from each other that is different (i.e., larger or smaller) than the first spacing. To account for this difference in spacing, interconnects 840 with different standoff heights and/or diameters may be used.

Referring now to FIG. 8A, a cross-sectional illustration of an electronic system 850 is shown, in accordance with an embodiment. In an embodiment, the electronic system 850 includes package substrate 820 and a board 810. The package substrate 820 may include any suitable substrate 825 material. In some instances, the substrate 825 may include organic buildup layers, such as buildup film or the like. The substrate 820 may include a core (not shown). The core may be an organic core, a glass core, or the like. In an embodiment, conductive routing (e.g., pads, traces, vias, etc.) may be provided in and/or on the substrate 825. Components, such as, but not limited to, passives (e.g., capacitors, inductors, resistors, etc.) may be embedded within the substrate 825. Bridge substrates for linking together multiple overlying dies may also be embedded in or provided over the substrate 825. In an embodiment, the board 810 may be a printed circuit board (PCB) or the like. In yet another embodiment, the board 810 and/or the package substrate may be replaced with any suitable substrate used in an electronic system 850 package. For instance, the board 810 and/or the package substrate 820 may be replaced by an interposer (e.g., an organic interposer, a glass interposer, etc.).

In an embodiment, pads 827 may be provided on a surface of the substrate 825. The pads 827 may be copper pads or the like. The pads 827 may comprise seed layers, barrier layers, or the like. Copper in the pads 827 may be alloyed with any suitable alloying element in some instances. In the illustrated embodiment, the pads 827 are recessed into the substrate 825 so that bottom surfaces of the pads 827 are substantially coplanar with a bottom surface of the substrate 825. In other embodiments, the pads 827 may extend out past a bottom surface of the substrate 825.

Similarly, pads 817 may be provided on the board 810. The pads 817 may be electrically conductive metallic pads that are similar in composition and structure to those of pads 827. The pads 817 may be recessed into the board 810, or the pads 817 may extend out past a top surface of the board 810. In an embodiment, each pad 817 in the board 810 may correspond to an individual pad 827 in the substrate 825. In some instances, the paired pads 817 and 827 may have similar diameters.

In an embodiment, a plurality of different interconnects 840 may be provided between the board 810 and the package substrate 820. The interconnects 840 may provide electrical, thermal, and mechanical coupling between the board 810 and the package substrate 820. In the particular embodiment shown in FIG. 8A, there are four different interconnects 840A-840D. The interconnects 840A-840D may have similar dimensions (e.g., standoff height, diameter, etc.).

However, the material composition of each of the interconnects 840A-840D may be different. A different material composition may refer to either a difference in the elements within a given interconnect 840 or a difference in weight percentage of different elements within a given interconnect 840. Different elemental compositions may be useful for providing different reflow temperatures and/or for providing different electrical performances. For example, some solder compositions may have more favorable electrical conductivity metrics. In some embodiments, a solder composition used for an interconnect may comprise tin, silver, and copper (i.e., SAC) or a solder composition may include bismuth and tin. Though, other low temperature solder formulations may also be used in some instances. In other embodiments, the different interconnects 840 may include the same elemental constituents with different weight percentages. For example, a difference in the weight percent of an element in both interconnects 840 may be approximately one percent or greater, approximately five percent or greater, or approximately ten percent or greater.

Referring now to FIG. 8B, a cross-sectional illustration of an electronic system 850 is shown, in accordance with an additional embodiment. In an embodiment, the electronic system 850 in FIG. 8B may be substantially similar to the electronic system 850 in FIG. 8A, with the exception of the fourth type of interconnect 840D. Instead of having an elemental composition difference, the fourth interconnect 840D has a structural difference. More particularly, the interconnect 840D has a core 841 and a shell 842 around the core 841.

The core 841 can be used to prevent collapse of the interconnect 840D during reflow. For example, the shell 842 may melt (or reflow) at a particular temperature, whereas the core 841 remains solid at that particular temperature. Since the core 841 remains solid, the package substrate 820 is prevented from moving closer to the board 810. This provides a more consistent standoff height for the BGA between the package substrate 820 and the board 810. As will be described in greater detail below, such core 841 based interconnects 840 are particularly beneficial for use towards the corners of the electronic system 850.

In an embodiment, the core 841 may be any material that has a higher melting point than a melting point of the shell 842. For example, the shell 842 may be a low temperature solder such as a SAC solder or a bismuth-tin solder, and the core 841 may comprise copper with (or without) any alloying or trace elements. Though, other materials, such as, but not limited to, other metallic elements, high temperature polymers, ceramics, and the like may be used as the core 841. In the illustrated embodiment, the shell 842 is shown as having a different shading than the interconnects 840A-840C to indicate that shell 842 has a different material composition. Though, in some embodiments, the shell 842 may have a material composition that is similar or the same as one of the other interconnects 840A-840C.

In addition to having options for material choice for the core 841, the structure of the core 841 may also be varied. In the illustrated embodiment, the core 841 has a spherical shape. In other embodiments, the core 841 may be a rectangular prism or any other three dimensional shape. For example, the core 841 may be considered a column in some embodiments. The core 841 may also have other structures, such as a spring.

In the illustrated embodiment, a single core 841 based interconnect 840 is shown as one example. However, it is to be appreciated that embodiments may include an array of interconnects 840 that include two or more different core 841 based interconnects. Two core 841 based interconnects may be different from each other in many different ways. For example, the materials used for the cores 841 may be different, the materials used for the shells 842 may be different, the dimensions of the cores 841 may be different, or the shape of the cores 841 may be different.

Referring now to FIG. 8C, a cross-sectional illustration of an electronic system 850 is shown, in accordance with yet another embodiment. The electronic system 850 in FIG. 8C may be similar to the electronic system 850 in FIG. 8A, with the exception of the structure of the interconnects 840. In FIG. 8C, differences between interconnects 840 may include having different dimensions. For example, the interconnect 840A may have a first diameter, the interconnect 840B may have a second diameter, and the interconnect 840C may have a third diameter. The first diameter, the second diameter, and the third diameter may all be different from each other. In order to accommodate the different diameters, the pads 817 and 827 may also have non-uniform sizes.

In an embodiment, having a “different dimension” may refer to a pair of interconnects 840 that have a difference in the dimension of interest that is at least ten percent. In some instances, a first diameter of interconnect 840A may be approximately twenty percent different than a second diameter of interconnect 840B at a similar stand-off height of solder with no greater than ten percent difference (between the stand-off heights). As an example, in a particular embodiment, the first diameter is approximately 150 μm and the second diameter is approximately 200 μm, while the stand-off height is approximately 210 μm for first interconnect 840A and 820 μm for second interconnect 840B. In such an instance, the two interconnects 840A and 840B would be considered “different” from each other.

In the illustrated embodiment, each of the interconnects 840A-840C have different shadings in order to indicate that they have different material compositions. However, it is to be appreciated that the difference in dimension (e.g., diameter) may be the only difference between two “different” interconnect 840 types. That is, in some embodiments, the interconnects 840A-840C may all have the same material composition.

In the illustrated embodiment, the sidewall profiles of each of the interconnects 840A-840C with different dimensions are substantially the same. However, as the diameter of the interconnect 840 changes, the profile of the sidewall may also change. For example, the sidewall profiles may have a more vertical (or nearly vertical) profile in some instances, whereas other dimensions may result in even more curvature than what is shown in FIG. 8C. That is, differences in sidewall profiles may also be a way to identify “different” types of interconnects 840.

In FIGS. 8A-8C, various categories to identify “differences” between the interconnects 840 are shown. In FIG. 8A, material compositions are highlighted. In FIG. 8B, structural differences are highlighted. In FIG. 8C, dimensional differences are highlighted. However, it is to be appreciated that “different” interconnects may include any of the different categories described herein. For example, within a single BGA between the board 810 and the package substrate 820, interconnects 840 may have differences including one or more of material composition, structure, and dimensions.

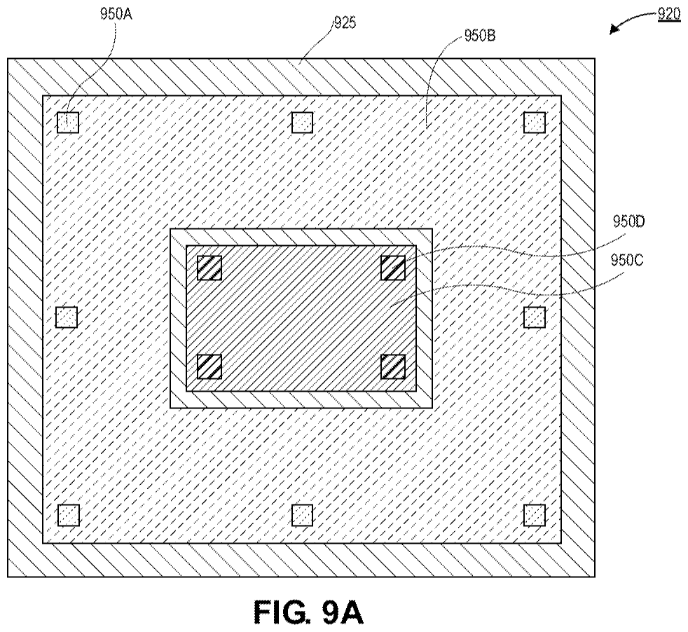

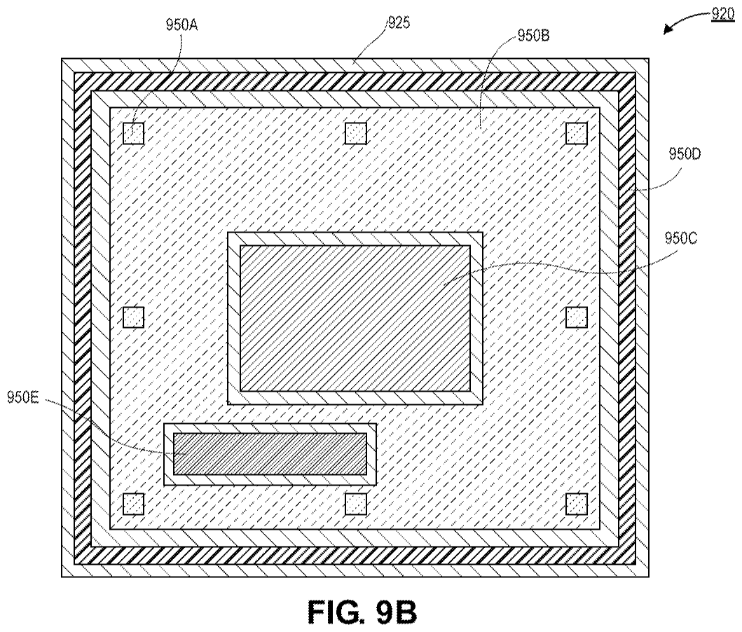

Referring now to FIG. 9A, a plan view illustration of a package substrate 920 is shown, in accordance with an embodiment. In an embodiment, the package substrate 920 may include any suitable substrate 925. For example, the substrate 925 may be an organic substrate with (or without) a core. In FIG. 9A, a plurality of regions 950 are shown across the surface of the substrate 925. The regions 950 may together form a BGA that is provided between the package substrate 920 and another substrate (such as a board).

In an embodiment, the regions 950 depict locations where different types of interconnects (not shown) are provided. One or more interconnects may be provided in each of the regions 950. The area of each region should not be considered as directly corresponding with a number of interconnects. That is, a first region 950 that has an area that is twice as large as a second region 950 does not necessarily indicate that the first region has twice as many interconnects compared to the second region 950. More generally, the different regions 950 show general locations where it may be useful to use different types of interconnects.

There are four different types of regions 950A-950D shown in FIG. 9A. First regions 950A are smaller and are provided in islands near the edge of the package substrate 920. These locations, especially towards the corners of the package substrate 920, are beneficial locations for interconnects with core architectures. This allows for improved standoff height uniformity between substrates since the interconnects cannot be fully compressed during reflow. A second region 950B may be formed in a ring around a third region 950C. The second region 950B and the third region 950C may use interconnects for different purposes. For example, one may include HSIO interconnects, and the other may include power/ground interconnects. As such, electrical performance metrics of the interconnects in the second region 950B and the third region 950C may ideally be different from each other. Finally, fourth regions 950D may be provided as islands within the third region 950C. The fourth regions 950D may also include interconnects with core architectures in order to prevent solder collapse during reflow processes.

Referring now to FIG. 9B, a plan view illustration of a package substrate 920 is shown, in accordance with an additional embodiment. The package substrate 920 in FIG. 9B may be similar to the package substrate 920 in FIG. 9A, with the exception of the layout and number of different regions 950. For example, FIG. 9B includes five different regions 950A-950E.

In an embodiment, the first regions 950A are provided as islands proximate to the edges of the substrate 925. The first regions 950A may be locations where interconnects with core architectures are desirable to improve standoff height uniformity. The second region 950B may be a ring around the third region 950C. The second region 950B and the third region 950C may have interconnects that include different electrical requirements in some instances. Other differences may include the dimensions of the interconnects in order to mitigate solder bridging or non-contact opens. The fourth region 950D may be ring that is provided around a perimeter of the second region 950B. The fourth region 950D may be proximate to edges of the package substrate 920. The fourth region 950D may have interconnects with different electrical or mechanical metrics than other regions 950. Finally, a fifth region 950E may be an island within the second region 950B. In some embodiments, the fifth region 950E may be a high performance region, and the interconnects may need particularly high electrical conductivity.

In FIGS. 9A and 9B the layout of the regions 950 are provided as specific examples, and should not be considered as being limiting to embodiments described herein. Regions 950 may take any footprint area, have any shape, may be arranged in any order, or many other potential differences. More generally, FIGS. 9A and 9B are used to illustrate that electrical and mechanical considerations of an electronic package can be accounted for through the selection of an n-ball solution. Each different interconnect type can be chosen to optimize a given performance metric that is desired for a certain area in the BGA.

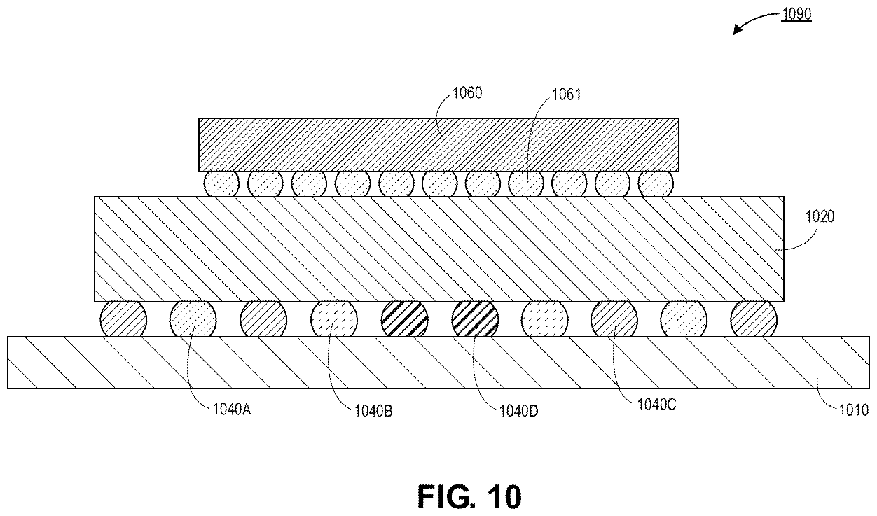

Referring now to FIG. 10, a cross-sectional illustration of an electronic system 1090 is shown, in accordance with an embodiment. In an embodiment, the electronic system 1090 includes a board 1010, such as a PCB. The board 1010 may be coupled to a package substrate 1020 by interconnects 1040. The package substrate 1020 may be an organic package substrate with (or without) a core.

In an embodiment, the interconnects 1040 may be any suitable interconnect architecture. For example, the interconnects 1040 may be a BGA interconnect architecture. The interconnects 1040 may have an n-ball architecture. That is, within a single interconnect level, there may be a plurality of different types of interconnects 1040. For example, the interconnects 1040 in FIG. 10 include four different types of interconnects 1040A-1040D. Though, embodiments may include three or more, four or more, five or more, six or more, etc. different types of interconnects 1040.

The interconnects 1040 may be different from each other in many different ways. For example, interconnects 1040 may comprise different material compositions. Different material compositions may include different alloy systems (e.g., SAC or tin-bismuth) or different elemental compositions within a single alloy system. Differences between interconnects 1040 may also include dimensional differences (e.g., diameter or standoff height). The difference between the interconnects 1040 may also be structural. For example, one or more of the interconnects 1040 may include a core with a shell around the core.

In an embodiment, one or more dies 1060 may be coupled to the package substrate 1020 through interconnects 1061. The interconnects 1061 may be any first level interconnect (FLI) architecture. For example, interconnects 1061 may be solder bumps, copper bumps, hybrid bonding architectures, or the like. The die 1060 may be a compute die such as a CPU, a GPU, an XPU, or any other type of processor. Die 1060 may also include a memory die or any other peripheral die useful for the electronic system 1090.

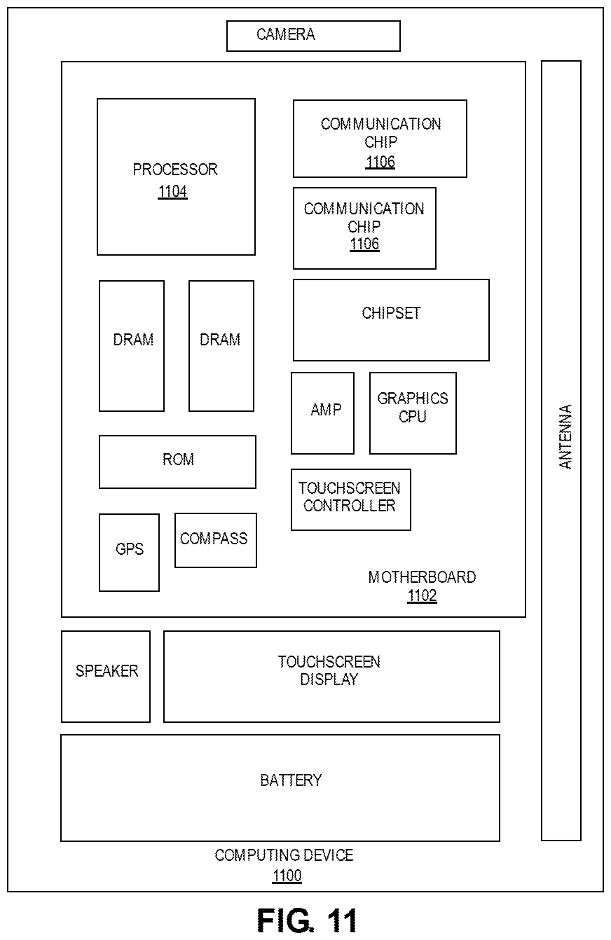

FIG. 11 illustrates a computing device 1100 in accordance with one implementation of the disclosure. The computing device 1100 houses a board 1102. The board 1102 may include a number of components, including but not limited to a processor 1104 and at least one communication chip 1106. The processor 1104 is physically and electrically coupled to the board 1102. In some implementations the at least one communication chip 1106 is also physically and electrically coupled to the board 1102. In further implementations, the communication chip 1106 is part of the processor 1104.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 1106 enables wireless communications for the transfer of data to and from the computing device 1100. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1106 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 1100 may include a plurality of communication chips 1106. For instance, a first communication chip 1106 may be dedicated to shorter range wireless communications such as Wi-Fi and Bluetooth and a second communication chip 1106 may be dedicated to longer range wireless communications such as GPS, EDGE, GPRS, CDMA, WiMAX, LTE, Ev-DO, and others.

The processor 1104 of the computing device 1100 includes an integrated circuit die packaged within the processor 1104. In some implementations of the disclosure, the integrated circuit die of the processor may be part of an electronic package that includes SLIs between substrates that include three or more different interconnect architectures, in accordance with embodiments described herein. The term “processor” may refer to any device or portion of a device that processes electronic data from registers and/or memory to transform that electronic data into other electronic data that may be stored in registers and/or memory.

The communication chip 1106 also includes an integrated circuit die packaged within the communication chip 1106. In accordance with another implementation of the disclosure, the integrated circuit die of the communication chip may be part of an electronic package that includes SLIs between substrates that include three or more different interconnect architectures, in accordance with embodiments described herein.

In an embodiment, the computing device 1100 may be part of any apparatus. For example, the computing device may be part of a personal computer, a server, a mobile device, a tablet, an automobile, or the like. That is, the computing device 1100 is not limited to being used for any particular type of system, and the computing device 1100 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example 1: an apparatus, comprising: a substrate; and a ball grid array across a surface of the substrate, wherein the ball grid array comprises: first interconnects in a first region of the ball grid array; second interconnects in a second region of the ball grid array; third interconnects in a third region of the ball grid array; and fourth interconnects in a fourth region of the ball grid array; and wherein the first interconnects, the second interconnects, the third interconnects, and the fourth interconnects all have a difference in one or more of a composition, a dimension, and a structure.

Example 2: the apparatus of Example 1, wherein the first interconnects comprise a first solder composition, and wherein the second interconnects comprise a second solder composition that is different than the first solder composition.

Example 3: the apparatus of Example 2, wherein the first solder composition comprises tin, copper, and silver, and wherein the second solder composition comprises bismuth and tin.

Example 4: the apparatus of Example 2, wherein the first solder composition and the second solder composition comprise the same elemental constituents, and wherein a weight percentage of one or more of the elemental constituents in the first solder composition is different than a weight percentage of a corresponding one or more of the elemental constituents in the second solder composition.

Example 5: the apparatus of Examples 1-4, wherein the first interconnects comprise a first diameter, and the second interconnects comprise a second diameter that is different than the first diameter.

Example 6: the apparatus of Example 5, wherein the first diameter is at least 10 percent larger than the second diameter.

Example 7: the apparatus of Examples 1-6, wherein the first interconnects comprise a core and a shell.

Example 8: the apparatus of Example 7, wherein the core is a copper core, a polymer core, a spring, or a pillar.

Example 9: the apparatus of Examples 1-8, wherein the first region is a ring adjacent to a perimeter of the substrate.

Example 10: the apparatus of Examples 1-9, wherein the first region comprises four sub-regions, wherein each sub-region is proximate to a corner of the substrate, and wherein one first interconnect is located in each sub-region.

Example 11: an apparatus, comprising: a first substrate; a second substrate over the first substrate; and a plurality of interconnects between the first substrate and the second substrate, wherein the plurality of interconnects comprise four or more different interconnect types.

Example 12: the apparatus of Example 11, wherein one or both of the first substrate and the second substrate have curved top and/or bottom surfaces, and wherein a distance between an edge of the first substrate and an edge of the second substrate is greater than a distance between a center of the first substrate and a center of the second substrate.

Example 13: the apparatus of Example 12, wherein a first interconnect proximate to the center of the first substrate has a first diameter, and wherein a second interconnect proximate to the edge of the first substrate has a second diameter that is greater than the first diameter.

Example 14: the apparatus of Examples 11-13, wherein at least two of the four or more interconnect types have different material compositions.

Example 15: the apparatus of Example 14, wherein a first interconnect type comprises tin, silver, and copper, and wherein a second interconnect type comprises bismuth and tin.

Example 16: the apparatus of Examples 11-15, wherein at least one of the four or more interconnect types has a core.

Example 17: the apparatus of Example 16, wherein the core comprises a copper core, a polymer core, a spring, or a pillar.

Example 18: an apparatus, comprising: a board; a package substrate over the board; interconnects between the package substrate and the board, wherein the interconnects comprise four or more different interconnect architectures; and a die over the package substrate.

Example 19: the apparatus of Example 18, wherein the four or more different interconnect architectures comprise differences in one or more of an elemental composition, a diameter, a standoff height, and a structure.

Example 20: the apparatus of Example 18 or Example 19, wherein the apparatus is part of a personal computer, a server, a mobile device, a tablet, or an automobile.

What is claimed is:

1. An apparatus, comprising:
a substrate; and
a ball grid array across a surface of the substrate, wherein the ball grid array comprises:
first interconnects in a first region of the ball grid array;
second interconnects in a second region of the ball grid array;
third interconnects in a third region of the ball grid array; and
fourth interconnects in a fourth region of the ball grid array; and
wherein the first interconnects, the second interconnects, the third interconnects, and the fourth interconnects all have a difference in one or more of a composition, a dimension, and a structure.

2. The apparatus of claim 1, wherein the first interconnects comprise a first solder composition, and wherein the second interconnects comprise a second solder composition that is different than the first solder composition.

3. The apparatus of claim 2, wherein the first solder composition comprises tin, copper, and silver, and wherein the second solder composition comprises bismuth and tin.

4. The apparatus of claim 2, wherein the first solder composition and the second solder composition comprise the same elemental constituents, and wherein a weight percentage of one or more of the elemental constituents in the first solder composition is different than a weight percentage of a corresponding one or more of the elemental constituents in the second solder composition.

5. The apparatus of claim 1, wherein the first interconnects comprise a first diameter, and the second interconnects comprise a second diameter that is different than the first diameter.

6. The apparatus of claim 5, wherein the first diameter is at least 10 percent larger than the second diameter.

7. The apparatus of claim 1, wherein the first interconnects comprise a core and a shell.

8. The apparatus of claim 7, wherein the core is a copper core, a polymer core, a spring, or a pillar.

9. The apparatus of claim 1, wherein the first region is a ring adjacent to a perimeter of the substrate.

10. The apparatus of claim 1, wherein the first region comprises four sub-regions, wherein each sub-region is proximate to a corner of the substrate, and wherein one first interconnect is located in each sub-region.

11. An apparatus, comprising:
a first substrate;
a second substrate over the first substrate; and
a plurality of interconnects between the first substrate and the second substrate, wherein the plurality of interconnects comprise four or more different interconnect types.

12. The apparatus of claim 11, wherein one or both of the first substrate and the second substrate have curved top and/or bottom surfaces, and wherein a distance between an edge of the first substrate and an edge of the second substrate is greater than a distance between a center of the first substrate and a center of the second substrate.

13. The apparatus of claim 12, wherein a first interconnect proximate to the center of the first substrate has a first diameter, and wherein a second interconnect proximate to the edge of the first substrate has a second diameter that is greater than the first diameter.

14. The apparatus of claim 11, wherein at least two of the four or more interconnect types have different material compositions.

15. The apparatus of claim 14, wherein a first interconnect type comprises tin, silver, and copper, and wherein a second interconnect type comprises bismuth and tin.

16. The apparatus of claim 11, wherein at least one of the four or more interconnect types has a core.

17. The apparatus of claim 16, wherein the core comprises a copper core, a polymer core, a spring, or a pillar.

18. An apparatus, comprising:
a board;
a package substrate over the board;
interconnects between the package substrate and the board, wherein the interconnects comprise four or more different interconnect architectures; and
a die over the package substrate.

19. The apparatus of claim 18, wherein the four or more different interconnect architectures comprise differences in one or more of an elemental composition, a diameter, a standoff height, and a structure.

20. The apparatus of claim 18, wherein the apparatus is part of a personal computer, a server, a mobile device, a tablet, or an automobile.
